(19) United States
(12) Patent Application Publication
(10) Pub. No.: US 2010/0073087 A1
(43) Pub. Date: Mar. 25, 2010

(54) Cable Television Network

(75) Inventor: Andre Van den Wyngaert, Mechelen (BE)

Correspondence Address: BARNES & THORNBURG LLP, P.O. BOX 2786, CHICAGO, IL, 60690-2786, US

(73) Assignee: TECHNETIX GROUP LIMITED, West Sussex (GB)

(21) Appl. No.: 12/554,397

(22) Filed: Sep. 4, 2009

(30) Foreign Application Priority Data
Sep. 23, 2008 (GB) 0817383.3

(51) Int. Cl. H03F 1/00

(52) U.S. Cl. 330/150

(57) ABSTRACT

There is provided a cable television network (10) comprising a first amplifier (12) and a plurality of successive amplifiers (14, 14′, 14″) all connected in series electrically, with the first amplifier (12) connected to a power source (16) and power for each amplifier routed through the preceding amplifier, wherein at least some of the plurality of successive amplifiers (14, 14′, 14″) further comprise a power delay device (34, 34′, 34″) in the form of a relay such that the successive amplifiers are connected to power at different times to reduce current load on each amplifier. Each relay (34, 34′, 34″) receives electrical power from the preceding amplifier and introduces a power delay of between 100 and 1500 ms and more preferably 220-1000 ms.

### FIELD OF THE INVENTION

This invention relates to a cable television network with a plurality of amplifiers.

### BACKGROUND TO THE INVENTION

Cable television networks used for supplying broadband and television signals to users rely on a number of amplifiers used in series with passive elements such as distribution taps and other lengths of coaxial cable. The amplifiers are all fed by one mains alternating current (AC) power supply placed near one of the amplifiers in the network with the AC power on the same coaxial cable as the radio frequency (RF) signal used for data transmission throughout the network. Each amplifier in the line consumes some power, and also passes power from its input to its output to feed the next amplifier.

Each amplifier has a built-in direct current (DC) power supply to convert the incoming AC power to a stabilised +24V DC power. This power supply has a large input smoothing capacitor. If the amplifiers are powered down due to maintenance or as a result of mains power failure, when power is restored each amplifier draws a big current spike as the smoothing capacitor charges up. This can cause fuses associated with the amplifiers to blow and often means that technicians have to go out and replace fuses, causing disruption to users.

### SUMMARY OF THE INVENTION

In accordance with the invention, there is provided a cable television network comprising a first amplifier and a plurality of successive amplifiers, all connected in series electrically, with the first amplifier connected to a power source and power for each amplifier routed through the preceding amplifier, wherein at least some of the plurality of successive amplifiers further comprise a power delay means such that the successive amplifiers are connected to power at different times to reduce current load on each amplifier. The power supplied to amplifier lags behind power to the preceding amplifier such that the amplifiers switch on one-by-one at a time interval determined by the power delay means. The power thus cascades down the plurality of successive amplifiers until all amplifiers are switched on. This reduces the maximum current spike that any amplifier experiences and ensures fuses are not blown.

Preferably all of the plurality of successive amplifiers further comprise a power delay means so that the power supply to each of the successive amplifiers is staggered from the preceding successive amplifier.

The power delay means may be in communication with some or all of the plurality of successive amplifiers, introducing a time delay into the power supplied for each successive amplifier so as to achieve staggered power connection to the amplifiers.

Particularly desirably the power delay means comprises a plurality of power delay devices, each power delay device associated with one successive amplifier.

In accordance with another aspect of the present invention there is provided an amplifier for use in a cable television network, wherein the amplifier is in communication with a power delay device to delay power supplied.

The power delay device may comprise a relay or similar switch means which upon receiving power, introduces a delay in the power reaching the successive amplifier.

Preferably the power delay device introduces a power delay of between 100 and 1500 ms and more preferably 220-1000 ms. The delay chosen depends on voltage but should be sufficiently long that the current spike associated with supplying power to a preceding successive amplifier has ended before the next power delay device operates to supply power to the next successive amplifier.

Preferably each power delay device receives electrical power from the preceding amplifier.

The power delay device may be separable from the amplifier and so may be in series with or replace an input fuse of each successive amplifier. Alternatively, the power delay device may be in series with an input or output of the successive amplifier.

If desired, the power delay device may be integral with the amplifier, for example contained on a circuit board inserted directly into the successive amplifier.

The invention will now be described, by way of example, with reference to the accompanying drawings in which:

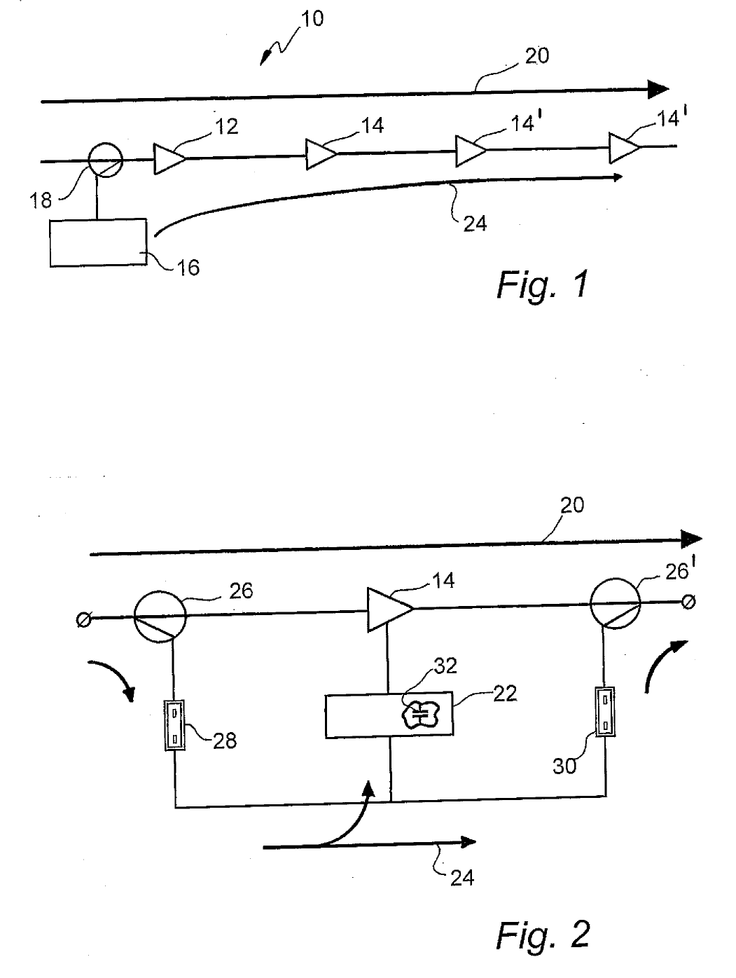

FIG. 1 shows a schematic diagram of a cable television network comprising a plurality of amplifiers;

FIG. 2 shows a schematic diagram of a standard amplifier;

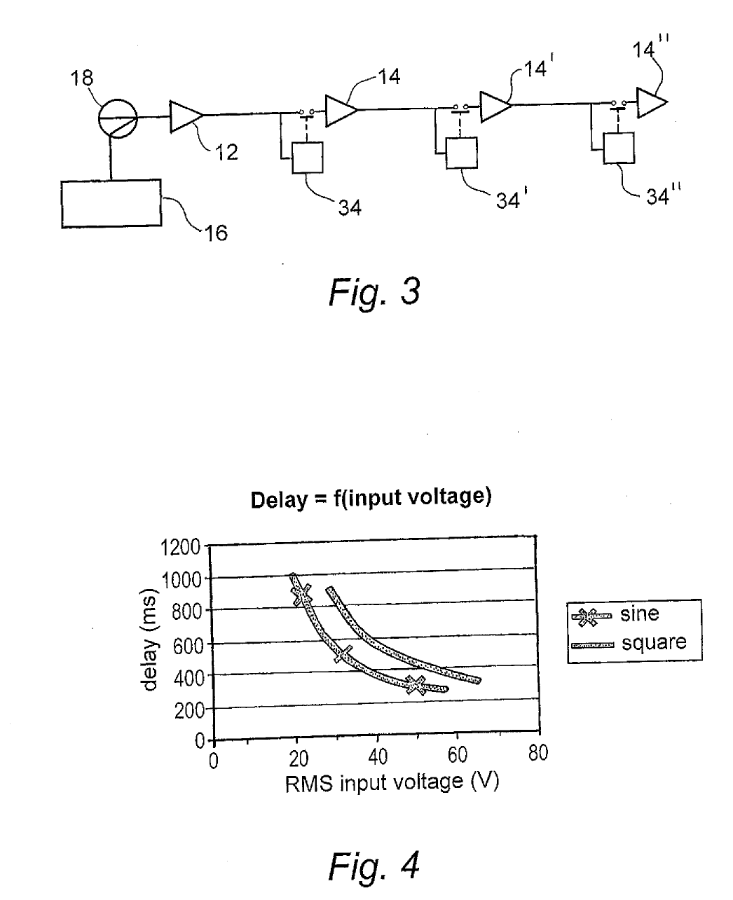

FIG. 3 shows a schematic diagram of a network using the present invention; and

FIG. 4 depicts a graph showing time delay against input voltage.

### DESCRIPTION

FIG. 1 shows a schematic diagram of a cable television (CATV) network 10 in which a number of amplifiers, four of which are shown by way of example, are used in series with passive elements such as distribution taps and lengths of coaxial cable associated with individual users. All the amplifiers 12, 14, 14′, 14″ are fed by one mains AC power supply 16 placed near one of the amplifiers in the network using power inserter 18. In this case, the power supply is placed near amplifier 12. Typically all the amplifiers are connected together using a coaxial cable along which both the AC power 24 and the RF signal 20 pass. Each amplifier 12, 14, 14′, 14″ consumes some power and also passes the power from its input to its output to feed the next amplifier in the succession of amplifiers within the network.

FIG. 2 is a simplified illustration of how each amplifier is connected into the network. Each amplifier 12, 14 has a built-in DC power supply 22 to convert incoming AC power 24 to a stabilised +24V DC power for the amplifier stages. The AC power is directed from the main coaxial cable by power inserters 26, 26′ and associated input fuse 28 and output fuse 30. Two fuses are shown by way of example, but each amplifier can have two or more fuses, one for the input port and one for each available output port. By means of selecting the values of these fuses, the installer can select where he wants the power to come from and where it should go.

The DC power supply 22 has a large input smoothing capacitor 32. When the whole system is powered down due to maintenance or due to a mains power failure, restoring power will cause each amplifier to draw a big current spike as the smoothing capacitor charges up. A current spike for a small amplifier with a small built-in switching power supply is almost 22 amps, although a 1 Ohm series resistor used to measure the current decreases its true value, and thus the current spike is actually above 22 amp.

Where two or more amplifiers are placed in series in a CATV network, the resulting spike is higher, i.e. more current, and wider, lasts longer, than the spike from one amplifier. This can cause the input fuse of the first amplifier and also fuses of other amplifiers to blow. Thus when a mains failure is experienced, often technicians have to go out and replace fuses on individual amplifiers throughout the network which delays restoring the connection to the consumer.

It is not possible to bypass the fuses for a few seconds as the power is switched on as this will cause problems elsewhere in the network, and replacing fuses with metal bridges or higher-value fuses is not safe as it may cause damage on printed circuit boards or other conductors.

To solve the problem of fuses blowing as power is restored to the network, the invention proposes using a delay circuit in association with the amplifiers, as shown in FIG. 3. The mains power supply 16 is shown associated with a first amplifier 12, although the power supply could be associated with any amplifier in the network. However, importantly, the amplifier which the mains power supply is connected to, which for the sake of ease of discussion will be called the first amplifier, does not have a delay circuit associated with it. All other amplifiers, 14, 14′, 14″ have a delay circuit 34, 34′ and 34″ associated with them. Power to the amplifiers 14, 14′, 14″ and other amplifiers in the network other than amplifier 12, is delayed by virtue of the time delay of circuit 34. The delay circuit 34 is typically a delayed relay contact in series with, or instead of, the input fuse of the amplifier and can either be built into a small separate housing or integral with the amplifier. As has been mentioned before, the first amplifier 12 must not be equipped with such a relay.

Once power has been interrupted to the network and is then restored, the first amplifier 12 powers up immediately as it has no delay circuit. The first amplifier passes power to the relay contact 34 in front of amplifier 14 and after a time delay set by the relay, usually of the order of a few hundred ms and typically 200 ms, the relay contact closes to power up the second amplifier. Power then passes to the relay contact associated with amplifier 14′ and again after 200 ms, the relay switch closes to restore power to amplifier 14′ and so on down the line of amplifiers. Thus where there is a line of amplifiers N, the first amplifier will power up immediately and then each successive amplifier n will be powered up at a time T=(n−1)Δt where n is from 1 to N. Thus if there are a total of ten amplifiers in the system, the last amplifier will switch on at a time 9 Δt after the first amplifier, i.e. 1800 ms after the first amplifier switches on.

By staggering the time at which each amplifier switches on in a cascade along the network, the large current peak caused by the inrush current of all amplifiers together is now spread over several smaller peaks with intervals of Δt i.e. 200 ms. None of the fuses in the network will blow.

If another power failure occurs, all relays 34 will open and when the power is restored again, the whole cycle starts again.

The relay circuits are designed to remain closed for one second after a power failure so that when a short-circuit occurs on the network and the voltage drops to near zero, the contacts remain closed for one second. This provides sufficient time for a fuse in the network to blow, usually the input fuse of the first amplifier 12, thus maintaining the original fuse protection throughout the remainder of the network.

The additional power consumption from all the delay relay circuits is very small since each relay only needs 10 mA to work.

The delay circuit can be a simple transistor based circuit with an RC network driving a 10 amp relay. The delay will be voltage dependent as is shown for a tested prototype in FIG. 4 where the delay varied between 220 and 1000 ms. Since the peak value of the sine wave and the square wave voltage are different when they have the same RMS value, there is also a delay difference between sine wave and square wave.

The delay circuit can be built into a small separate unit to be mounted onto any amplifier input or output port anywhere in the network, so as to serve as a time-delay valve for the power without impacting any of the RF characteristics of the network. In this instance, two power inserters must also be built into the unit. Another way of implementing the delay is to use a dedicated circuit board inserted directly into the amplifier instead of a fuse. For each type and brand of amplifier, a different board must be designed to give appropriate time delay characteristics.

1. A cable television network comprising a first amplifier and a plurality of successive amplifiers, all connected in series electrically, with the first amplifier connected to a power source and power for each amplifier routed through the preceding amplifier, wherein at least some of the plurality of successive amplifiers further comprise a power delay circuit such that the successive amplifiers are connected to power at different times to reduce current load on each amplifier.

2. A cable television network according to claim 1, wherein all of the plurality of successive amplifiers further comprise a power delay circuit.

3. A cable television network according to claim 1, wherein the power delay circuit is in communication with some or all of the plurality of successive amplifiers.

4. A cable television network according to claim 1, wherein the power delay circuit comprises a plurality of power delay devices, each power delay device associated with one successive amplifier.

5. A cable television network according to claim 4, wherein each power delay device receives electrical power from a preceding amplifier.

6. A cable television network according to claim 4, wherein the power delay device comprises a relay or similar switch.

7. A cable television network according to claim 4, wherein the power delay device introduces a power delay of between 100 and 1500 ms and more preferably 220-1000 ms.

8. A cable television network according to claim 4, wherein the power delay device is in series with or replaces an input fuse of each successive amplifier.

9. A cable television network according to claim 4, wherein the power delay device is in series with an input or output of the successive amplifier.

10. A cable television network according to claim 4, wherein the power delay device is contained on a circuit board inserted directly into the successive amplifier.

11. An amplifier for use in a cable television network, wherein the amplifier is in communication with a power delay device.

12. An amplifier according to claim 11, wherein the power delay device comprises a relay or similar switch.

13. An amplifier according to claim 11, wherein the power delay device introduces a power delay of between 100 and 1500 ms and more preferably 220-1000 ms.

14. An amplifier according to claim 11, wherein the power delay device is in series with or replaces an input fuse.

15. An amplifier according to claim 11, wherein the power delay device is in series with an input or output.

16. An amplifier according to claim 11, wherein the power delay device is contained on an integral circuit board.
